(19) United States
(12) Patent Application Publication
(10) Pub. No.: US 2025/0120135 A1
(43) Pub. Date: Apr. 10, 2025

(54) SUPERJUNCTION SEMICONDUCTOR DEVICE

(71) Applicant: FUJI ELECTRIC CO., LTD., Kawasaki-shi (JP)

(72) Inventors: Syunki NARITA, Matsumoto-city, Nagano (JP); Shinsuke HARADA, Tsukuba-shi, Ibaraki (JP)

(73) Assignee: FUJI ELECTRIC CO., LTD., Kawasaki-shi (JP)

(21) Appl. No.: 18/889,597

(22) Filed: Sep. 19, 2024

(30) Foreign Application Priority Data
Oct. 4, 2023 (JP) 2023-173268

(51) Int. Cl. H01L 29/06; H01L 29/16; H01L 29/78

(52) U.S. Cl. CPC H10D 62/111; H10D 30/665; H10D 30/668; H10D 62/8325

(57) ABSTRACT

A semiconductor device includes, in an active region and a termination region of a semiconductor substrate, a parallel pn layer in which regions of a first conductivity type and regions of a second conductivity type are disposed repeatedly alternating with each other. The semiconductor device further includes a third semiconductor region of the second conductivity type, configuring a voltage withstanding structure, in the termination region. Each of the regions of the second conductivity type includes multiple sub-regions stacked on one another, the multiple sub-regions including a topmost subregion that is closest to a first main surface of the semiconductor substrate. The third semiconductor region is formed at least partially by the plurality of topmost sub-regions in the termination region.

### CROSS REFERENCE TO RELATED APPLICATIONS

This application is based upon and claims the benefit of priority of the prior Japanese Patent Application No. 2023-173268, filed on Oct. 4, 2023, the entire contents of which are incorporated herein by reference.

### BACKGROUND OF THE INVENTION

### 1. Field of the Invention

Embodiments of the disclosure relate to a superjunction semiconductor device.

### 2. Description of the Related Art

Japanese Laid-Open Patent Publication No. 2021-089916 describes a silicon carbide semiconductor device having a drift layer that includes a superjunction structure (SJ structure) in which parallel pn layers of a three-layer structure are sequentially stacked. The pn layers have the same structure in an active region, an edge termination region, and an intermediate region, which connects the active region and edge termination region.

### SUMMARY OF THE INVENTION

According to an embodiment of the present disclosure, a superjunction semiconductor device includes: a semiconductor substrate containing silicon carbide, the semiconductor substrate having an active region and a termination region surrounding a periphery of the active region in a plan view of the superjunction semiconductor device, the semiconductor substrate having a first main surface and a second main surface opposite to each other; a first semiconductor layer of a second conductivity type, provided in the semiconductor substrate at the first main surface thereof, the first semiconductor layer having a first surface and a second surface opposite to each other, the second surface facing the second main surface of the semiconductor substrate; a parallel pn layer in which a plurality of regions of a first conductivity type and a plurality of regions of the second conductivity type are disposed alternating with each other in a direction parallel to the first main surface of the semiconductor substrate, the parallel pn layer being provided in the semiconductor substrate, in both the active region and the termination region; a first semiconductor region of the first conductivity type, selectively provided in the first semiconductor layer, at the first surface of the first semiconductor layer, in the active region; a plurality of trenches penetrating through the first semiconductor region and the first semiconductor layer, each trench terminating in the semiconductor substrate; a plurality of gate insulating films respectively provided in the plurality of trenches; a plurality of gate electrodes respectively provided in the plurality of trenches on the plurality of gate insulating films; a first electrode provided on the first main surface of the semiconductor substrate, the first electrode being electrically connected to the first semiconductor region; a second electrode provided on the second main surface of the semiconductor substrate; and a third semiconductor region of the second conductivity type, selectively provided in the termination region between the first main surface of the semiconductor substrate and the parallel pn layer, the third semiconductor region surrounding the periphery of the active region in the plan view and configuring a voltage withstanding structure, the third semiconductor region being electrically connected to the first electrode. Each of the plurality of regions of the second conductivity type in the parallel pn layer includes a plurality of sub-regions of the second conductivity type stacked on one another, the plurality of sub-regions including a topmost sub-region that is closest to the first main surface of the semiconductor substrate. The third semiconductor region is formed at least partially by the plurality of topmost sub-regions in the termination region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of an active region of a SJ-MOSFET according to an embodiment.

FIG. 2 is a cross-sectional view depicting a structure of an intermediate region and an edge termination region of the SJ-MOSFET according to the embodiment.

FIG. 3 is a cross-sectional view depicting a state of a parallel pn layer of the SJ-MOSFET according to the embodiment during manufacture.

FIG. 4 is a cross-sectional view depicting a state of the parallel pn layer of the SJ-MOSFET according to the embodiment during manufacture.

FIG. 5 is a cross-sectional view depicting a state of the parallel pn layer of the SJ-MOSFET according to the embodiment during manufacture.

FIG. 6 is a cross-sectional view depicting an edge termination region of a conventional SJ-MOSFET in detail.

### DETAILED DESCRIPTION OF THE INVENTION

First, problems associated with the conventional technique are discussed. In a conventional silicon carbide semiconductor device with a SJ structure, a problem arises in that charge becomes unbalanced in the edge termination region.

An outline of an embodiment of the present disclosure is described. (1) A superjunction semiconductor device according to an embodiment of the present disclosure is as follows. In a semiconductor substrate that contains silicon carbide, an active region is provided. In the semiconductor substrate, a termination region that surrounds a periphery of the active region is provided. A first semiconductor layer of a second conductivity type is provided at a first main surface of the semiconductor substrate. In the active region and the termination region, a parallel pn layer in which regions of a first conductivity type and regions of a second conductivity type are disposed repeatedly alternating with one another in a direction parallel to the first main surface of the semiconductor substrate is provided in the semiconductor substrate. In the active region, a first semiconductor region of the first conductivity type is selectively provided in the first semiconductor layer, at a first surface thereof opposite to a second surface thereof facing a second main surface of the semiconductor substrate. A trench that penetrates through the first semiconductor region and the first semiconductor layer and terminates in the semiconductor substrate is provided. In the trench, a gate electrode is provided via a gate insulating film. On the first main surface of the semiconductor substrate, a first electrode that is electrically connected to the first semiconductor region is provided. On the second main surface of the semiconductor substrate, a second electrode is provided. In the termination region, between the first main surface of the semiconductor substrate and the parallel pn layer, a third semiconductor region of the second conductivity type is selectively provided surrounding the periphery of the active region, the third semiconductor region being electrically connected to the first electrode and configuring a voltage withstanding structure. Each of the regions of a second conductivity type is constituted by multiple sub-regions of the second conductivity type stacked on one another and of the sub-regions of the second conductivity type, one closest to the first main surface of the semiconductor substrate also constitutes the third semiconductor region.

According to the disclosure above, a p-type region constituting an uppermost portion of the p-type regions (the regions of the second conductivity type) of the parallel pn layer also serves as a p-type region (third semiconductor region of the second conductivity type) configuring a JTE structure and the p-type region constituting the uppermost portion of the parallel pn layer functions as the JTE structure. Thus, overlap of the p-type regions of the parallel pn layer and the p-type region configuring the JTE structure is eliminated and in the edge termination region, the charge may be suppressed from becoming unbalanced. Furthermore, formation of a p-type region specifically to configure the JTE structure becomes unnecessary thereby, enabling simplification of the processes for forming the semiconductor device and reductions in manufacturing costs.

(2) Further, the superjunction semiconductor device according to the present disclosure, in (1) above, further includes a second semiconductor region of the second conductivity type, provided at a bottom of the trench, and a surface of the second semiconductor region facing the second main surface of the semiconductor substrate and a surface of the third semiconductor region facing the second main surface of the semiconductor substrate may be at a same depth.

According to the disclosure above, the p-type regions, the p-type region configuring the JTE structure, and a bottom of a p⁺-type region are aligned linearly. Thus, corner portions of the bottom of the p⁺-type region are eliminated and the concentration of electric field at the corner portions can be suppressed.

(3) Further, in the superjunction semiconductor device according to the present disclosure, in (2) above, a thickness of the second semiconductor region may be equal to a thickness of the third semiconductor region.

Findings underlying the present disclosure are described. First, problems related to a conventional superjunction semiconductor device are discussed. Conventionally, a semiconductor device is commonly known in which a drift layer is constituted by a superjunction (SJ) structure having a parallel pn layer in which n-type regions and p-type regions are disposed adjacently and repeatedly alternate with one another in a direction parallel to a main surface of a substrate. The n-type regions and the p-type regions configuring the parallel pn layer extend in a striped pattern parallel to a main surface of a semiconductor substrate (semiconductor chip). The n-type regions and the p-type regions configuring the parallel pn layer are provided substantially uniformly in substantially the entire semiconductor substrate, from an active region in a center (chip center) of the semiconductor substrate to an end (chip end) of the semiconductor substrate.

A structure of the conventional silicon carbide semiconductor device with a SJ structure is described taking a metal oxide semiconductor field effect transistor (MOSFET) having an insulated gate with a three-layer metal-oxide-semiconductor structure as an example. FIG. 6 is a cross-sectional view depicting an edge termination region of a conventional SJ-MOSFET in detail.

A conventional SJ-MOSFET 150 depicted in FIG. 6 has a general trench gate structure in an active region of a semiconductor substrate (semiconductor chip) 140 containing silicon carbide and is vertical MOSFET having a SJ structure in which a drift layer 102 constituted by a parallel pn layer 151. The semiconductor substrate 140 has a substantially rectangular shape in a plan view. The active region has a substantially rectangular shape in a plan view and is provided in a center (chip center) of the semiconductor substrate 140. A periphery of the active region is surrounded by an edge termination region 130 via an intermediate region 120.

In the intermediate region 120, a gate wiring layer (not depicted) such as a gate finger is disposed. The edge termination region 130 is a region between the intermediate region 120 and an end (chip end) of the semiconductor substrate 140. In the edge termination region 130, as a voltage withstanding structure, a junction termination extension (JTE) structure 132 and an n⁺-type channel stopper region (not depicted) are disposed. The JTE structure 132 surrounds the periphery of the active region via the intermediate region 120.

The parallel pn layer 151 is provided uniformly in substantially an entire area of the semiconductor substrate 140, from the active region to the edge termination region 130. The parallel pn layer 151 is a SJ structure in which n-type regions 152 and p-type regions 153 are disposed adjacently and repeatedly alternate with one another in a first direction X that is parallel to the front surface of the semiconductor substrate 140. The n-type regions 152 and the p-type regions 153 of the parallel pn layer 151 extend in a striped pattern in a second direction Y that is parallel to the front surface of the semiconductor substrate 140 and orthogonal to the first direction X.

The n-type regions 152 and the p-type regions 153 of the parallel pn layer 151 are disposed in substantially an entire area of the edge termination region 130, directly beneath the JTE structure 132 and the n⁺-type channel stopper region (on a side thereof facing an n⁺-type drain region 101). The parallel pn layer 151 is adjacent to the JTE structure 132 and the n⁺-type channel stopper region in a depth direction Z around an entire periphery of the JTE structure 132 and the n⁺-type channel stopper region and reaches the front surface of the semiconductor substrate 140 between the JTE structure 132 and the n⁺-type channel stopper region.

A cross-section of the structure of the conventional SJ-MOSFET 150 is described. The semiconductor substrate 140 is formed by sequentially stacking epitaxial layers 142, 143 constituting the drift layer 102 and a p-type base region 104 on an n⁺-type starting substrate 141 containing silicon carbide. A main surface of the semiconductor substrate 140 where the p-type epitaxial layer 143 is provided is assumed to be a front surface while a main surface where the n⁺-type starting substrate 141, which constitutes the n⁺-type drain region 101, is provided is assumed to be a back surface. The epitaxial layer 142 is a portion constituting the drift layer (drift region) 102 and includes the parallel pn layer 151.

A portion of the p-type epitaxial layer 143 in the edge termination region 130 is removed by etching, thereby forming a step 131 at the front surface of the semiconductor substrate 140. In the edge termination region 130, the n⁻-type epitaxial layer 142 is exposed at the front surface of the semiconductor substrate 140. A p-type region 133 configuring the JTE structure 132 and the n⁺-type channel stopper region are each selectively provided in the n⁻-type epitaxial layer 142.

The p-type region 133 of the JTE structure 132 is fixed to a potential of a source electrode (not depicted) via p⁺-type regions 111, 112a and the p-type base region 104, which extend closer to the end of the semiconductor substrate 140 from the active region than is the step 131.

The n-type regions 152 and the p-type regions 153 of the parallel pn layer 151 are disposed at equal intervals in an entire area of the semiconductor substrate 140, from the active region to the edge termination region 130. The n-type regions 152 and the p-type regions 153 of the parallel pn layer 151 are disposed directly beneath the p⁺-type region 111 in the intermediate region 120, are disposed directly beneath the p-type region 133 in the edge termination region 130, and are in contact with the p⁺-type region 111 and the p-type region 133 in the depth direction Z.

Carrier concentrations (dopant concentrations) and widths (widths in the first direction X) of the n-type regions 152 and the p-type regions 153 of the parallel pn layer 151 are each set so that charge is balanced between the n-type regions 152 and the p-type regions 153 that are adjacent to one another in the parallel pn layer 151.

Charge being balanced means that a charge amount expressed by a product of the width and the carrier concentration of the n-type regions 152 and a charge amount expressed by a product of the width and the carrier concentration of the p-type regions 153 are substantially the same within a range that includes an allowable error due to process variation. A field oxide film 114 is provided on the p-type region 133 of the JTE structure 132 and the semiconductor substrate 140.

Here, in the conventional SJ-MOSFET 150, the JTE structure 132 is formed to sustain a breakdown voltage of the edge termination region 130. In the edge termination region 130, the p-type regions 153 of the parallel pn layer 151 overlap the p-type region 133 of the JTE structure 132 and in these overlapping regions (in FIG. 6, regions S101), the dopant concentration is the sum of the dopant concentration of the p-type regions 153 of the parallel pn layer 151 and the dopant concentration of the p-type region 133 of the JTE structure 132. Thus, a problem arises in that, in the edge termination region 130, the charge becomes unbalanced. Further, the p⁺-type region 111 is formed deeper than is the p-type region 133 of the JTE structure 132 and thus, at a bottom of the p⁺-type region 111, corner portions (in FIG. 6, S102) are formed and electric field concentrates at these corner portions.

Embodiments of a superjunction semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described.

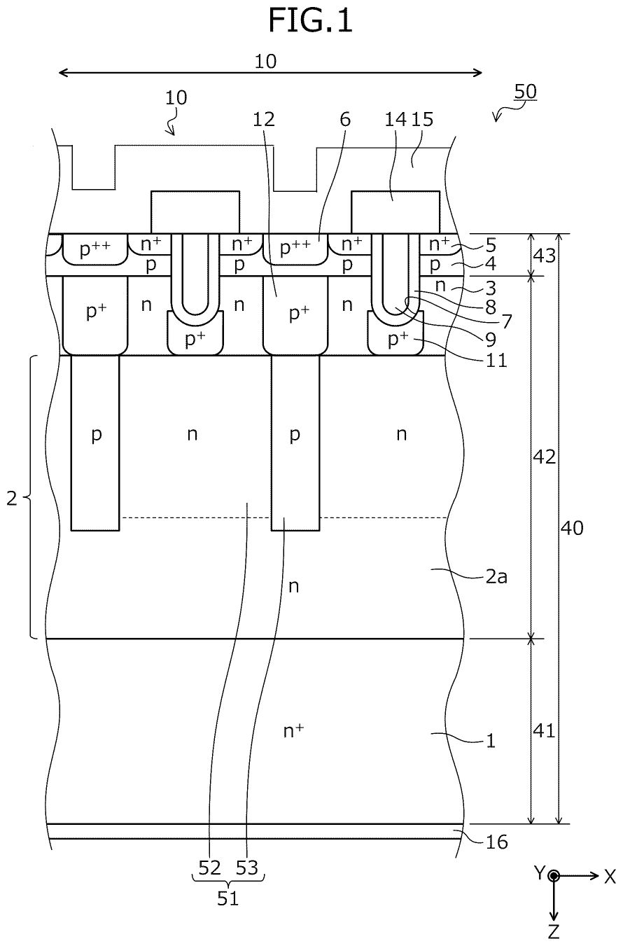

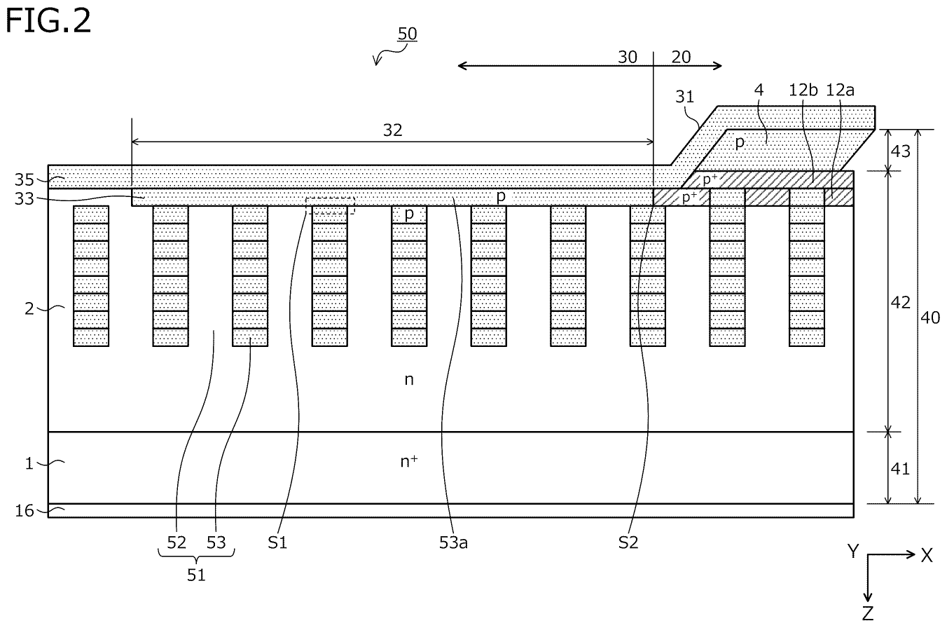

A superjunction semiconductor device according to an embodiment solving the problems above is described. A structure of the superjunction semiconductor device according to the embodiment is described taking a SJ-MOSFET as an example. FIG. 1 is a cross-sectional view depicting a structure of an active region of the SJ-MOSFET according to the embodiment. FIG. 2 is a cross-sectional view depicting a structure of an intermediate region and an edge termination region of the SJ-MOSFET according to the embodiment.

FIG. 1 depicts one unit cell (configuration unit of a device) of multiple unit cells each having a same structure and disposed in an active region 10. FIG. 2 depicts a region from a vicinity of a border between an intermediate region 20 and an edge termination region 30 to an end (chip end) of a semiconductor substrate 40.

A SJ-MOSFET 50 according to the embodiment depicted in FIGS. 1 and 2 is a vertical MOSFET having the semiconductor substrate (semiconductor chip) 40, which contains silicon carbide (SiC) and has the active region 10, the intermediate region 20, and the edge termination region 30, the vertical MOSFET further having a trench gate structure (device structure) in which a drift layer (drift region) 2 has a SJ structure constituted by a parallel pn layer 51 from the active region 10 to the edge termination region 30. The active region 10 is a region through which a main current flows when the MOSFET is in an on state and is disposed in a center (chip center) of the semiconductor substrate 40.

As depicted in FIG. 1, in the active region 10, a general trench gate structure is provided in the semiconductor substrate 40, at a front surface of the semiconductor substrate 40. The trench gate structure is configured by a p-type base region (first semiconductor layer of a second conductivity type) 4, n⁺-type source regions (first semiconductor regions of a first conductivity type) 5, p⁺⁺-type contact regions 6, gate trenches 7, gate insulating films 8, and gate electrodes 9. The semiconductor substrate 40 is formed by sequentially depositing epitaxial layers 42, 43 constituting the drift layer 2 and the p-type base region 4, on a front surface of an n⁺-type starting substrate 41 containing silicon carbide.

A main surface of the semiconductor substrate 40 where the p-type epitaxial layer 43 is provided is assumed to be a front surface while a main surface where the n⁺-type starting substrate 41 is provided is assumed to be a back surface (second main surface). The n⁺-type starting substrate 41 constitutes an n⁺-type drain region 1. The gate trenches 7 penetrate through the p-type epitaxial layer 43 from the front surface of the semiconductor substrate 40 in the depth direction Z and reach (terminate) in the n⁻-type epitaxial layer 42.

The gate trenches 7, for example, extend in a striped pattern in a direction parallel to the front surface of the semiconductor substrate 40 (herein, the second direction Y). In the gate trenches 7, the gate electrodes 9 are provided via the gate insulating films 8. The p-type base region 4, the n⁺-type source regions 5, and the p⁺⁺-type contact regions 6 are selectively provided between the gate trenches 7 that are adjacent to each other. The p-type base region 4 is a portion of the p-type epitaxial layer 43 excluding the n⁺-type source regions 5 and the p⁺⁺-type contact regions 6.

The n⁺-type source regions 5 and the p⁺⁺-type contact regions 6 are selectively provided between the front surface of the semiconductor substrate 40 and the p-type base region 4, with the n⁺-type source regions 5 and the p⁺⁺-type contact regions 6 being in contact with the p-type base region 4 and exposed at the front surface of the semiconductor substrate 40. Being exposed at the front surface of the semiconductor substrate 40 means being in contact with a source electrode 15, in contact holes of an interlayer insulating film 14. The p⁺⁺-type contact regions 6 are disposed farther from the gate trenches 7 than are the n⁺-type source regions 5.

The parallel pn layer 51 in the n⁻-type epitaxial layer 42, at the predetermined position described above. The parallel pn layer 51, for example, is formed using a multi-stage epitaxial method in which epitaxial growth of the n⁻-type epitaxial layer 42 constituting the drift layer 2 is divided into multiple stages and in each stage, regions constituting n-type regions (regions of the first conductivity type) 52 and p-type regions (regions of the second conductivity type) 53 are each selectively formed by ion implantation in the formed portion of the n⁻-type epitaxial layer 42 so that regions of the same conductivity type are adjacent to each other in the depth direction Z.

In the active region 10, between the p-type base region 4 and the parallel pn layer 51 (the drift layer 2), n-type current spreading regions 3 and p⁺-type regions 11, 12 are each selectively provided. The n-type current spreading regions 3 and the p⁺-type regions 11, 12, for example, are diffused regions formed in the n⁻-type epitaxial layer 42 by ion implantation. The n-type current spreading regions 3 and the p⁺-type regions 11, 12 are disposed at positions closer to the n⁺-type drain region 1 than are bottoms of the gate trenches 7 and extend linearly parallel to the gate trenches 7 in the second direction Y.

The n-type current spreading regions 3 constitute a so-called current spreading layer (CSL) that reduces carrier spreading resistance. Between the gate trenches 7 that are adjacent to each other, the n-type current spreading regions 3 are in contact with the p⁺-type regions 11, 12, the p-type base region 4, and the n-type regions 52 of the parallel pn layer 51; the n-type current spreading regions 3 reach positions closer to the n⁺-type drain region 1 than are the bottoms of the gate trenches 7. Instead of the n-type current spreading regions 3, portions of the n⁻-type epitaxial layer 42 free of ion implantation may be arranged.

The p⁺-type regions 11, 12 have a function of relaxing electric field applied to the bottoms of the gate trenches 7. The p⁺-type regions 12 are each in contact with a different one of the p-type regions 53 of the parallel pn layer 51 in the depth direction Z. The p⁺-type regions (second semiconductor regions of the second conductivity type) 11 are disposed apart from the p-type base region 4 and face the bottoms of the gate trenches 7 in the depth direction Z. The p⁺-type regions 12 are provided between the gate trenches 7 that are adjacent to each other; the p⁺-type regions 12 are in contact with the p-type base region 4 but are apart from the p⁺-type regions 11 and the gate trenches 7.

The interlayer insulating film 14 is provided in an entire area of the first main surface of the semiconductor substrate 40 so as to cover the gate electrodes 9 embedded in the gate trenches 7. The source electrode (first electrode) 15 is in contact with the n⁺-type source regions 5 and the p⁺⁺-type contact regions 6 via the contact holes opened in the interlayer insulating film 14. The source electrode 15 is electrically insulated from the gate electrodes 9 via the interlayer insulating film 14. A drain electrode (second electrode) 16 is provided at the back surface (back surface of the n⁺-type starting substrate 41) of the semiconductor substrate 40.

The edge termination region 30, as depicted in FIG. 2, is a region between the intermediate region 20 and the end of the semiconductor substrate 40 and surrounds a periphery of the active region 10 via the intermediate region 20. The intermediate region 20 is adjacent to the active region 10 and surrounds the periphery of the active region 10. The intermediate region 20 and the edge termination region 30 have a SJ structure in which the drift layer 2 is constituted by the parallel pn layer 51.

The edge termination region 30 has a function of relaxing electric field of the drift layer 2 in the active region 10 and the intermediate region 20, toward the front surface (first main surface) of the semiconductor substrate 40 and sustaining a breakdown voltage. The breakdown voltage is a voltage limit at which leakage current does not increase excessively and no malfunction or damage of the device occurs. As a voltage withstanding structure, a junction termination extension (JTE) structure 32 configured by a p-type region (third semiconductor region of the second conductivity type) 33, and an n⁺-type channel stopper region (not depicted) are disposed in the edge termination region 30. The JTE structure 32 surrounds the periphery of the active region 10 via the intermediate region 20.

A portion of the p-type epitaxial layer 43 in the edge termination region 30 is removed by etching, thereby forming a step 31 at the front surface of the semiconductor substrate 40. A portion of the front surface of the semiconductor substrate 40 in the edge termination region 30 and bordered by the step 31 is recessed toward the n⁺-type drain region 1 as compared to a portion of the front surface of the semiconductor substrate 40 in the active region 10. In the edge termination region 30, the p-type epitaxial layer 43 is removed and thus, the portion of the front surface of the semiconductor substrate 40 in the edge termination region 30 is an exposed surface of the n⁻-type epitaxial layer 42.

The JTE structure 32 is a structure in which the p-type region 33 is disposed adjacent to and concentrically surrounding the periphery of the active region 10 via the intermediate region 20. The JTE structure 32 reduces electric field concentration closer to the end of the semiconductor substrate 40 than is the intermediate region 20 and may prevent device destruction due to application of a voltage less than a predetermined voltage (breakdown voltage of the edge termination region 30).

The parallel pn layer 51 is a SJ structure in which the n-type regions 52 and the p-type regions 53 are disposed adjacently and repeatedly alternate with one another in the first direction X, which is parallel to the front surface of the semiconductor substrate 40. The n-type regions 52 and the p-type regions 53 of the parallel pn layer 51 extend in a striped pattern to a vicinity of an end of the edge termination region 30 and the intermediate region 20, in the second direction Y, which is parallel to the front surface of the semiconductor substrate 40 and orthogonal to the first direction X.

The n-type regions 52 and the p-type regions 53 of the parallel pn layer 51 are in contact with the p⁺-type regions 11 of the intermediate region 20 in the depth direction Z. The p-type regions 53 of the parallel pn layer 51 are fixed to a potential of the source electrode 15 (refer to FIG. 1) via p⁺-type regions 12a.

In the edge termination region 30, the parallel pn layer 51 is disposed closer to the end of the semiconductor substrate 40 in the first direction X than is the outer end of the JTE structure 32 so that at least one of the p-type regions 53 is disposed closer to the end of the semiconductor substrate 40 in the first direction X than is the outer end of the JTE structure 32.

The p-type regions 53 of the parallel pn layer 51 are disposed closer to the end of the semiconductor substrate 40 in the first direction X than is the outer end of the JTE structure 32 and thus, when the MOSFET is off, concentration of the electric field in the JTE structure 32 at the outer end of the JTE structure 32 may be suppressed. The outer end of the JTE structure 32 is an outer end of the p-type region 33 of the JTE structure 32. Further, the parallel pn layer 51 may be disposed in a range so as to not be more than, for example, about 10 μm from the outer end of the JTE structure 32 in the first direction X.

By setting a range in which the parallel pn layer 51 is disposed from the outer end of the JTE structure 32 in the first direction X to be within the described range, the number of floating p-type regions 53 disposed in the edge termination region 30 is reduced. As a result, the amount of minority carriers (holes) that are stored in the edge termination region 30 due to switching of the MOSFET, etc. and remain without being discharged externally may be reduced. Thus, it is preferable for a fewer number of the p-type regions 53 to be disposed closer to the end of the semiconductor substrate 40 in the first direction X than is the outer end of the JTE structure 32.

In the edge termination region 30, the n-type regions 52 and the p-type regions 53 of the parallel pn layer 51 are in contact with the JTE structure 32 in the depth direction Z. The p-type regions 53 of the parallel pn layer 51 are fixed to the potential of the source electrode 15 (refer to FIG. 1) via the p⁺-type regions 12a, which are in contact with the JTE structure 32.

In the semiconductor substrate 40 near the front surface thereof, the p-type base region 4, the p⁺-type regions 12a corresponding to lower portions of the p⁺-type regions 12, and a p⁺-type region 12b corresponding to an upper portion of the p⁺-type regions 12 extend into the intermediate region 20 from the active region 10. The lower portions of the p⁺-type regions 12 are portions of the p⁺-type regions 12 of a same height as that of the p⁺-type regions 11 and the upper portions of the p⁺-type regions 12 are portions of the p⁺-type regions 12 closer to the source electrode 15 than are the p⁺-type regions 11.

In the intermediate region 20 and the edge termination region 30, an insulating layer in which a field oxide film 35 and the interlayer insulating film (not depicted) are sequentially stacked is provided on the front surface of the semiconductor substrate 40. In the intermediate region 20, a polysilicon (poly-Si) layer (not depicted) constituting a gate finger electrically connecting the gate electrodes 9 and a gate pad (not depicted), and a metal wiring layer (not depicted) are sequentially stacked on the field oxide film 35.

At the front surface of the semiconductor substrate 40, in the n⁻-type epitaxial layer 42, the p-type region 33 configuring the JTE structure 32 is selectively provided and the n⁺-type channel stopper region (not depicted) is selectively provided apart from the JTE structure 32, closer to the end of the semiconductor substrate 40 than is the JTE structure 32. The p-type region 33 configuring the JTE structure 32 is in contact with the p⁺-type regions 12a in a direction parallel to the front surface of the semiconductor substrate 40. The p-type region 33 configuring the JTE structure 32 is fixed to the potential of the source electrode 15 via the p⁺-type regions 12a.

As described, the p-type regions 53 and the p-type region 33 according to the embodiment are formed by ion implantation in the depth direction Z in the n⁻-type epitaxial layer 42 at each stage of epitaxial growth of the n⁻-type epitaxial layer 42. In the embodiment, a p-type region 53a (sub-region of the second conductivity type uppermost at the first main surface of the semiconductor substrate), which is an uppermost portion of the p-type regions 53, also serves as (constitutes) the p-type region 33 configuring the JTE structure 32 and the p-type region 53a functions as the JTE structure 32.

Thus, overlapping of the p-type regions 53 and the p-type region 33 configuring the JTE structure 32 is eliminated, a dopant concentration of a region S1 does not change from a dopant concentration of the p-type regions 53 and in the edge termination region 30, the charge may be suppressed from becoming unbalanced. Furthermore, formation of the p-type region 33 configuring the JTE structure 32 becomes unnecessary, whereby processes for forming the semiconductor device may be simplified and manufacturing costs may be reduced.

Further, a depth of the p-type region 53a is a same as a depth of the p⁺-type regions 12a and thus, the p-type region 53a, the p-type region 33 configuring the JTE structure 32, and bottoms of the p⁺-type regions 12a are aligned linearly in a region S2. As a result, corner portions of the bottoms of the p⁺-type regions 12a are eliminated and the concentration of electric field at the corner portions can be suppressed.

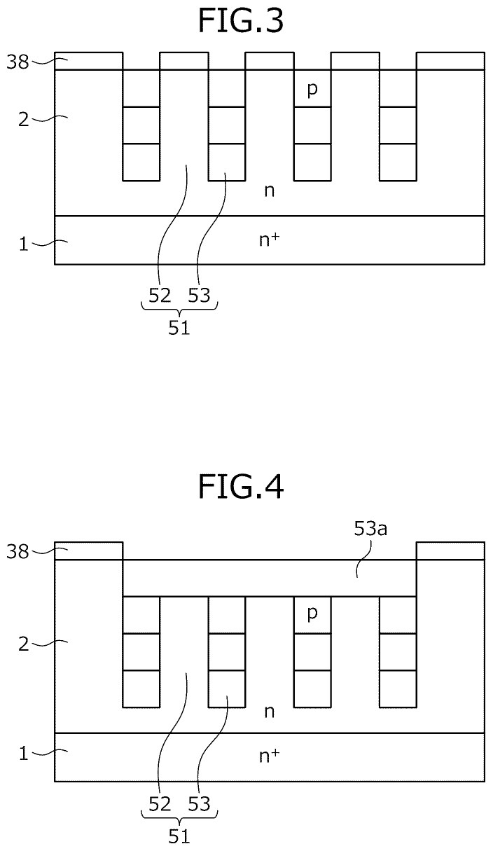

Next, a method of manufacturing the SJ-MOSFET 50 according to the embodiment is described. FIGS. 3, 4, and 5 are cross-sectional views depicting states of the parallel pn layer of the SJ-MOSFET according to the embodiment during manufacture. First, on a front surface of the n⁺-type starting substrate (semiconductor wafer) 41 constituting the n⁺-type drain region 1, the drift layer 2 including the parallel pn layer 51 is formed. For example, a multi-stage epitaxial method is used and the n⁻-type epitaxial layer 42 constituting the drift layer 2 is grown by dividing the epitaxy thereof into multiple stages (for example, 9 stages); and regions constituting the n-type regions 52 and the p-type regions 53 are selectively formed in a sublayer of the n⁻-type epitaxial layer 42 grown at each stage, by ion implantation so that regions of the same conductivity type are adjacent to one another in the depth direction Z.

At this time, in sublayers other an uppermost sublayer (for example, in an instance of 9 stages, first to eighth sublayers), as depicted in FIG. 3, a p-type dopant is implanted using an ion implantation mask 38 provided with openings at portions corresponding to the p-type regions 53. On the other hand, in the uppermost sublayer (for example, in the instance of 9 stages, a ninth sublayer), as depicted in FIG. 4, a p-type dopant is implanted using the ion implantation mask 38, which is opened at a portion corresponding to the p-type region 33 of the JTE structure 32. As a result, the p-type region 53a, which is the uppermost portion of the p-type regions 53 may be formed so as to function as the p-type region 33 configuring the JTE structure 32.

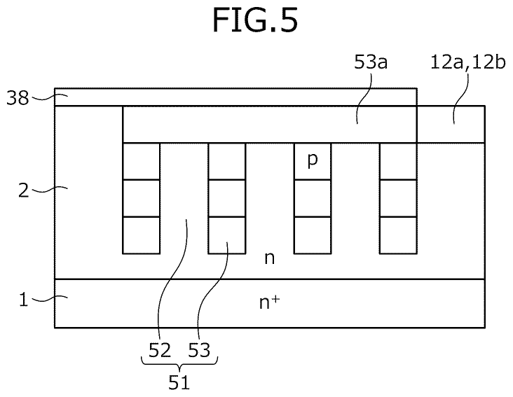

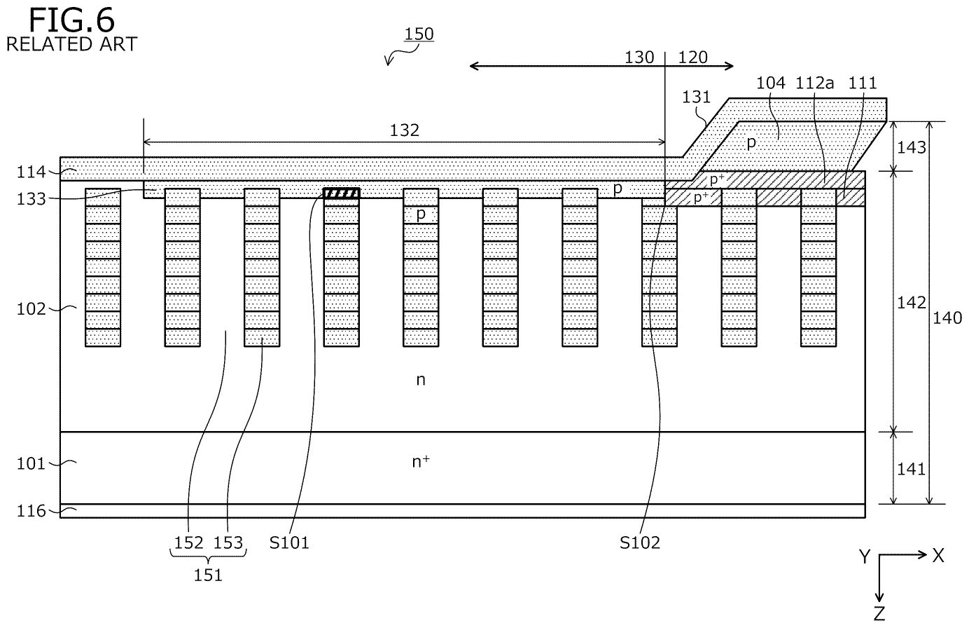

Next, in the active region 10, the n-type current spreading regions 3 and the p⁺-type regions 11, 12, 12a, 12b are formed in the parallel pn layer 51, at the surface thereof by ion implantation. In the intermediate region 20 and the edge termination region 30, as depicted in FIG. 5, a p-type dopant is implanted using the ion implantation mask 38 in which openings corresponding to the p⁺-type regions 12a, 12b are provided. At this time, the p⁺-type regions 12a, 12b are formed at the same depths as the p-type region 53a. The n-type current spreading regions 3 and the p⁺-type regions 12 may be divided into upper portions and lower portions, which are formed at corresponding stages of the epitaxy of the n⁻-type epitaxial layer 42, and the p⁺-type regions 11 may be formed concurrently with the p⁺-type regions 12a.

Next, the p-type epitaxial layer 43 constituting the p-type base region 4 is formed by epitaxy on the n⁻-type epitaxial layer 42. As a result, the semiconductor substrate (semiconductor wafer) 40 is fabricated in which the epitaxial layers 42, 43 are sequentially stacked on the n⁺-type starting substrate 41 and the epitaxial layer 42 includes the parallel pn layer 51. Next, a portion of the p-type epitaxial layer 43 in the edge termination region 30 is etched and removed, thereby forming the step 31 where a portion of the front surface of the semiconductor substrate 40 in the edge termination region 30 is lower than a portion of the front surface of the semiconductor substrate 40 in the active region 10. At this time, in the edge termination region 30, up to a portion corresponding to the p⁺-type region 12b is etched and removed. As a result, the p-type region 53a has a same thickness as a thickness of the p⁺-type regions 11a (refer to FIG. 2). The p-type region 53a is exposed at a front surface of the edge termination region 30. At a front surface of the active region 10 and the intermediate region 20, the p-type epitaxial layer 43 is exposed.

Next, the n⁺-type source regions 5, the p⁺⁺-type contact regions 6, and the n⁺-type channel stopper region are each selectively formed by ion implantation. A portion of the p-type epitaxial layer 43 excluding the n⁺-type source regions 5 and the p⁺⁺-type contact regions 6 constitutes the p-type base region 4.

Next, a heat treatment (hereinafter, activation annealing) for activating dopants ion-implanted into the epitaxial layers 42, 43 is performed. Next, the gate trenches 7, which penetrate through the n⁺-type source regions 5 and the p-type base region 4 from the front surface of the semiconductor substrate 40 and face the p⁺-type regions 11 in the n-type current spreading regions 3 are formed. Next, along the front surface of the semiconductor substrate 40 and inner walls of the gate trenches 7, the gate insulating films 8 are formed. Next, a polysilicon layer deposited on the front surface of the semiconductor substrate 40 so as to be embedded in the gate trenches 7 is etched back, leaving portions thereof constituting the gate electrodes 9 in the gate trenches 7.

In the intermediate region 20 and the edge termination region 30, the field oxide film 35 is formed at the front surface of the semiconductor substrate 40. In the intermediate region 20, a polysilicon layer (not depicted) constituting the gate finger is formed on the field oxide film 35. This polysilicon layer may be formed by a portion of the polysilicon layer deposited on the front surface of the semiconductor substrate 40 when the gate electrodes 9 are formed. Next, the interlayer insulating film (not depicted) is formed in an entire area of the front surface of the semiconductor substrate 40. Next, by a general method, surface electrodes (the source electrode 15, the gate pad, the metal wiring layer (not depicted), and the drain electrode 16) are formed at the front and back surfaces of the semiconductor substrate 40.

Next, portions of the front surface of the semiconductor substrate 40 other than a portion of the source electrode 15 (portion constituting a source pad), and portions where the gate pad and the metal wiring layer are provided are covered and protected by a passivation film (not depicted). Thereafter, the semiconductor wafer (the semiconductor substrate 40) is diced (cut) into individual chips, thereby completing the SJ-MOSFET 50 depicted in FIGS. 1 and 2.

As described, according to the embodiment, the p-type region constituting uppermost portions of the p-type regions of the parallel pn layer also serves (constitutes) as a p-type region configuring the JTE structure, and the p-type region constituting uppermost portions of the p-type regions of the parallel pn layer functions as the JTE structure. Thus, overlapping of the p-type regions of the parallel pn layer and the p-type region configuring the JTE structure is eliminated and in the edge termination region, the charge may be suppressed from becoming unbalanced. Furthermore, formation of a p-type region configuring the JTE structure becomes unnecessary, enabling simplification of the process of forming the semiconductor device and reductions in manufacturing costs.

In the foregoing, the present disclosure is not limited to the embodiments described and various modifications within a range not departing from the spirit of the disclosure are possible. For example, in the embodiments described, between the parallel pn layer and the n⁺-type starting substrate, the dopant concentration of a normal n-type drift region without a SJ structure may be higher than the dopant concentration of the n-type regions of the parallel pn layer. Further, the disclosure is similarly implemented when the conductivity types (n-type, p-type) are reversed.

The superjunction semiconductor device according to the present disclosure achieves an effect in that charge in the edge termination region may be suppressed from becoming unbalanced.

As described, the superjunction semiconductor device according to the present disclosure is useful for power semiconductor devices with a SJ structure used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A superjunction semiconductor device, comprising:
a semiconductor substrate containing silicon carbide, the semiconductor substrate having an active region and a termination region surrounding a periphery of the active region in a plan view of the superjunction semiconductor device, the semiconductor substrate having a first main surface and a second main surface opposite to each other;
a first semiconductor layer of a second conductivity type, provided in the semiconductor substrate at the first main surface thereof, the first semiconductor layer having a first surface and a second surface opposite to each other, the second surface facing the second main surface of the semiconductor substrate;
a parallel pn layer in which a plurality of regions of a first conductivity type and a plurality of regions of the second conductivity type are disposed alternating with each other in a direction parallel to the first main surface of the semiconductor substrate, the parallel pn layer being provided in the semiconductor substrate, in both the active region and the termination region;
a first semiconductor region of the first conductivity type, selectively provided in the first semiconductor layer, at the first surface of the first semiconductor layer, in the active region;
a plurality of trenches penetrating through the first semiconductor region and the first semiconductor layer, each trench terminating in the semiconductor substrate;
a plurality of gate insulating films respectively provided in the plurality of trenches;
a plurality of gate electrodes respectively provided in the plurality of trenches on the plurality of gate insulating films;
a first electrode provided on the first main surface of the semiconductor substrate, the first electrode being electrically connected to the first semiconductor region;
a second electrode provided on the second main surface of the semiconductor substrate; and
a third semiconductor region of the second conductivity type, selectively provided in the termination region between the first main surface of the semiconductor substrate and the parallel pn layer, the third semiconductor region surrounding the periphery of the active region in the plan view and configuring a voltage withstanding structure, the third semiconductor region being electrically connected to the first electrode, wherein
each of the plurality of regions of the second conductivity type in the parallel pn layer includes a plurality of sub-regions of the second conductivity type stacked on one another, the plurality of sub-regions including a topmost sub-region that is closest to the first main surface of the semiconductor substrate, and
the third semiconductor region is formed at least partially by the plurality of topmost sub-regions in the termination region.

2. The superjunction semiconductor device according to claim 1, further comprising a plurality of second semiconductor regions of the second conductivity type, each provided at a bottom of one of the plurality of trenches, wherein
each of the second semiconductor regions has a surface facing the second main surface of the semiconductor substrate, and
the third semiconductor region has a surface facing the second main surface of the semiconductor substrate, said surfaces of the second semiconductor regions and said surface of the third semiconductor region being at a same depth.

3. The superjunction semiconductor device according to claim 2, wherein the plurality of second semiconductor regions and the third semiconductor region are of a same thickness.
